(19) United States
(12) Patent Application Publication
(10) Pub. No.: US 2026/0090028 A1
(43) Pub. Date: Mar. 26, 2026

(54) Thin Film Transistor Having Capping Layer and Display Apparatus Comprising the Same

(71) Applicant: LG Display Co., Ltd., Seoul (KR)

(72) Inventors: Youngjin Yi, Paju-si (KR); Sohyung Lee, Paju-si (KR); Hyelim Ji, Paju-si (KR); Soyang Choi, Paju-si (KR); YounGyoung Chang, Paju-si (KR); JaeHyun Kim, Paju-si (KR)

(21) Appl. No.: 19/076,675

(22) Filed: Mar. 11, 2025

(30) Foreign Application Priority Data
Sep. 26, 2024 (KR) 10-2024-0131087

(51) Int. Cl. H10D 30/67; H10D 30/01; H10K 59/121

(52) U.S. Cl. CPC H10D 30/6736; H10D 30/0312; H10K 59/1213

(57) ABSTRACT

An embodiment of the present disclosure provides a thin film transistor including an active layer, a gate insulating layer on the active layer, a gate electrode on the gate insulating layer, and a capping layer on the gate insulating layer, wherein the gate electrode and the capping layer are spaced apart from each other, wherein a part of the active layer overlaps the gate electrode, and wherein another part of the active layer overlaps the capping layer, and provides a method for manufacturing a thin film transistor and display device including the same.

### CROSS-REFERENCE TO RELATED APPLICATION

This application claims the benefit of priority of the Republic of Korea Patent Application No. 10-2024-0131087 filed on Sep. 26, 2024, which is hereby incorporated by reference in its entirety.

### BACKGROUND

### Field of Technology

The present disclosure relates to a thin film transistor having a capping layer and a display device including the same.

### Discussion of the Related Art

Since thin film transistors can be manufactured on glass or plastic substrates, they are widely used as switching elements or driving elements in display devices such as liquid crystal display devices or organic light emitting devices.

Thin film transistors can be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, depending on the material constituting the active layer.

Among these, oxide semiconductor thin film transistors that have high mobility and a large resistance change depending on the oxygen content have the advantage of being able to easily obtain desired properties. Since the oxide constituting the active layer can be formed at a relatively low temperature during the manufacturing process of oxide semiconductor thin film transistors, the manufacturing cost is low. In addition, since oxide semiconductors are transparent due to the nature of oxides, they are also advantageous in implementing transparent displays.

High-resolution displays include a large number of thin film transistors. In order to arrange a large number of thin film transistors in a given area, the size of the thin film transistors must be reduced. However, when the size of the thin film transistor is reduced, the channel length also becomes shorter, which may deteriorate the operating stability of the thin film transistor or cause a characteristic deviation between multiple thin film transistors, which may deteriorate the display quality of the display device.

In order for a thin film transistor to operate stably, the channel must have an effective channel length greater than a certain value. In the case of a coplanar structure oxide semiconductor thin film transistor, control of the conductorized portion is important to secure the channel length.

In an oxide semiconductor thin film transistor, a phenomenon in which the conductorized portion penetrates into a channel may occur. If the length of the conductorized portion penetrated into the channel is not constant, the effective channel length of the thin film transistor is not constant, and thus characteristic deviations may occur between a plurality of thin film transistors.

An oxide semiconductor is sensitive to hydrogen. Hydrogen can make the properties of the oxide semiconductor unstable. In addition, electrical properties of the oxide semiconductor can change due to contact with hydrogen. For example, when an oxide semiconductor contacts hydrogen, the oxide semiconductor may lose its semiconductor properties and may have the properties of conductor. In detail, due to the penetration of hydrogen, oxygen vacancies Vo may occur in the oxide semiconductor, causing the oxide semiconductor to be conductorized.

As described above, hydrogen that has penetrated into the oxide semiconductor from the outside makes it difficult to predict or design the electrical characteristics of the oxide semiconductor thin film transistor. Therefore, it is necessary to control hydrogen in the oxide semiconductor thin film transistor. In addition, it is necessary to control the influence of hydrogen in the channel portion to secure a consistency of effective channel length.

### SUMMARY

One embodiment of the present disclosure provides a technology for selectively supplying hydrogen to an active layer using a capping layer.

One embodiment of the present disclosure provides a thin film transistor capable of having a constant effective channel length by controlling hydrogen using a capping layer.

One embodiment of the present disclosure provides a technology of selectively conductorizing an active layer using hydrogen while preventing the hydrogen from affecting a channel portion.

One embodiment of the present disclosure provides a method for manufacturing a thin film transistor, in which hydrogen is used for selective conductorization of an active layer while preventing the hydrogen from affecting a channel portion.

Another embodiment of the present disclosure is to provide a display device including the thin film transistor.

In accordance with an aspect of the present disclosure, the above and other objects may be accomplished by the provision of a thin film transistor including an active layer, a gate insulating layer on the active layer, a gate electrode on the gate insulating layer, and a capping layer on the gate insulating layer, wherein the gate electrode and the capping layer are spaced apart from each other, wherein a part of the active layer overlaps the gate electrode, and wherein another part of the active layer overlaps the capping layer.

The active layer may include a channel portion overlapping the gate electrode, an offset portion in contact with one side of the channel portion, and a connecting portion spaced apart from the channel portion and in contact with the offset portion. The connecting portion may overlap the capping layer, and the offset portion may not overlap the gate electrode and the capping layer.

The offset portion may be disposed between the channel portion and the connecting portion.

The connecting portion is a region in which an oxide semiconductor material is conductorized.

A carrier concentration of the offset portion may be higher than a carrier concentration of the channel portion and lower than a carrier concentration of the connecting portion.

A carrier concentration of the offset portion may increase along a direction from the channel portion toward the connecting portion.

The gate insulating layer may include at least one of silicon oxide SiOx, silicon nitride SiNx, and aluminum oxide AlOx.

The capping layer may include at least one of an oxide semiconductor material and a metal oxide.

In a region where the active layer and the capping layer overlap, an entire area between the active layer and the capping layer is filled with the gate insulating layer, and the capping layer may not be in contact with the active layer.

The capping layer may have a thickness of 10 nm to 300 nm.

The capping layer may contain a material different from a material contained in the gate electrode.

The thin film transistor may further include a source electrode and a drain electrode spaced apart from each other and contacting the active layer respectively, and at least one of the source electrode and the drain electrode may contacts the capping layer.

The active layer may include a first oxide semiconductor layer and a second oxide semiconductor layer on the first oxide semiconductor layer.

The gate insulating layer may include a first gate insulating layer and a second gate insulating layer on the first gate insulating layer, the capping layer may be disposed on the first gate insulating layer, and the gate electrode may be disposed on the second gate insulating layer.

Another embodiment of the present disclosure provides a method for manufacturing a thin film transistor including the steps of forming an active layer on a substrate, forming a gate insulating layer on the active layer, forming a capping layer on the gate insulating layer, heat treating the gate insulating layer, and forming a gate electrode on the gate insulating layer.

The heat treating temperature for the gate insulating layer may be in the range of 60° C. to 450° C.

Another embodiment of the present disclosure provides a display device including the thin film transistor described above.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line I-I′ of FIG. 1 according to one embodiment of the present disclosure.

FIG. 3 is a graph explaining a carrier concentration distribution in the active layer.

FIG. 4 is a graph explaining a distribution of sheet resistance in each region of the active layer.

FIG. 5 is a cross-sectional view of a thin film transistor according to another embodiment of the present disclosure.

FIG. 6 is a cross-sectional view of a thin film transistor according to another embodiment of the present disclosure.

FIG. 7 is a cross-sectional view of a thin film transistor according to another embodiment of the present disclosure.

FIG. 8 is a cross-sectional view of a thin film transistor according to another embodiment of the present disclosure.

FIG. 9A is a schematic diagram explaining a conventional conductorization method.

FIG. 9B is a schematic diagram explaining a conductorization penetration depth ΔL.

FIGS. 10A to 10F are schematic cross-sectional views explaining a method for manufacturing a thin film transistor according to another embodiment of the present disclosure.

FIG. 11 is a schematic diagram of a display device according to another embodiment of the present disclosure.

FIG. 12 is a circuit diagram for one pixel of FIG. 11 according to one embodiment.

FIG. 13 is a plan view of the pixels of FIG. 12 according to one embodiment.

FIG. 14 is a cross-sectional view taken along line II-II′ of FIG. 13 according to one embodiment.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. These embodiments are provided so that this disclosure will be thorough and complete and will fully understood by those skilled in the art.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be disposed “below”, or “beneath” another device may be disposed “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art may sufficiently understand. The embodiments of the present disclosure may be carried out independently from each other or may be carried out together in a co-dependent relationship.

In the addition of reference numerals to the components of each drawing describing embodiments of the present disclosure, the same components may have the same sign as may be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

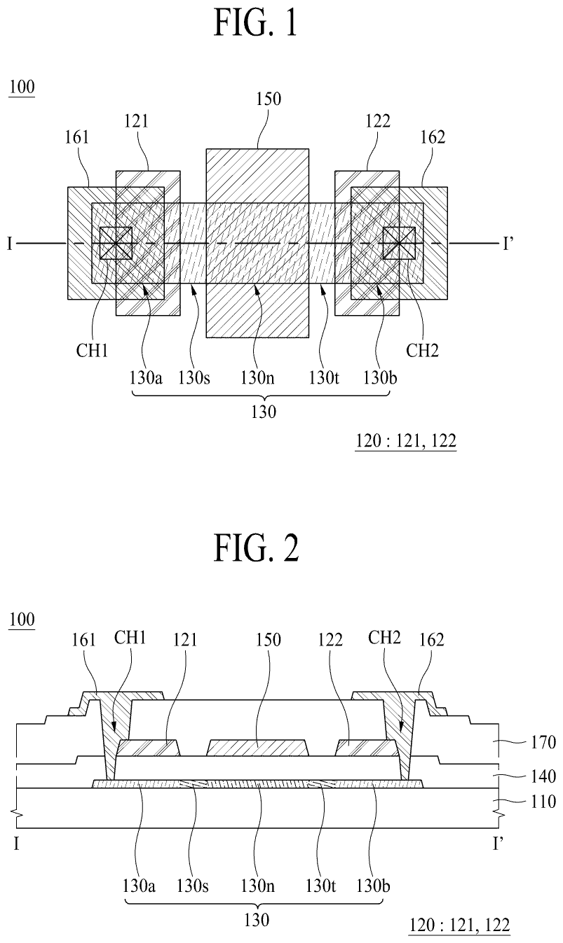

FIG. 1 is a plan view of a thin film transistor 100 according to one embodiment of the present disclosure, and FIG. 2 is a cross-sectional view taken along line I-I′ of FIG. 1 according to one embodiment of the present disclosure.

Referring to FIGS. 1 and 2, a thin film transistor 100 according to one embodiment of the present disclosure includes an active layer 130, a gate insulating layer 140 on the active layer 130, a gate electrode 150 on the gate insulating layer 140, and a capping layer 120 on the gate insulating layer 140. The gate electrode 150 is spaced apart from the active layer 130. A portion of the active layer 130 overlaps the gate electrode 150, and another portion of the active layer 130 overlaps the capping layer 120.

Referring to FIG. 2, a thin film transistor 100 may be disposed on a substrate 110.

The substrate 110 supports the components of the thin film transistor 100. Anything that supports the thin film transistor 100 can be called the substrate 110 without limitation.

The glass substrate or a polymer resin substrate may be used as the substrate 110. As a polymer resin substrate, there is a plastic substrate. The plastic substrate may include at least one of polyimide (PI), polycarbonate (PC), polyethylene (PE), polyester, polyethylene terephthalate (PET), and polystyrene (PS) having flexible properties. When a plastic is used as the substrate 110, considering that a high-temperature deposition process is performed on the substrate 110, a heat-resistant plastic that may withstand high temperatures may be used.

The active layer 130 is disposed on the substrate 110. According to one embodiment of the present disclosure, a buffer layer may be disposed on the substrate 110, and the active layer 130 may be disposed on the buffer layer (refer to FIG. 6).

According to one embodiment of the present disclosure, the active layer 130 includes an oxide semiconductor material. According to one embodiment of the present disclosure, the active layer 130 may be, for example, an oxide semiconductor layer made of an oxide semiconductor material.

The active layer 130 may include, for example, at least one of IGZO (InGaZnO)-based, IGO (InGaO)-based, IGZTO (InGaZnSnO)-based, GZTO (GaZnSnO)-based, GZO (GaZnO)-based, GO (GaO)-based, TO (SnO)-based, ITO (InSnO)-based, ITZO (InSnZnO)-based, IZO (InZnO)-based, ZO (ZnO)-based, InO-based, and FIZO (FeInZnO)-based oxide semiconductor material.

The active layer 130 may have a single layer structure or may have a multilayer structure including two or more oxide semiconductor layers.

According to one embodiment of the present disclosure, the active layer 130 includes a channel portion 130n, an offset portion 130s, 130t, and a connecting portion 130a, 130b.

The channel portion 130n overlaps the gate electrode 150. The channel portion 130n has semiconductor characteristics. Depending on the voltage applied to the gate electrode 150, the channel portion 130n may have electrical characteristics such as a conductor or electrical characteristics such as an insulator.

The offset portion 130s, 130t contacts one side of the channel portion 130n.

Referring to FIG. 2, the offset portion 130s, 130t may include a first offset portion 130s contacting one side of the channel portion 130n and a second offset portion 130t contacting the other side of the channel portion 130n. The channel portion 130n may be disposed between the first offset portion 130s and the second offset portion 130t.

The offset portion 130s, 130t does not overlap the gate electrode 150 and the capping layer 120. In a plan view, the offset portion 130s, 130t may be disposed between the gate electrode 150 and the capping layer 120.

The connecting portion 130a, 130b spaced apart from the channel portion 130n and contact the offset portion 130s, 130t. Referring to FIG. 2, the offset portion 130s, 130t may be disposed between the channel portion 130n and the connecting portions 130a, 130b.

The connecting portion 130a, 130b overlaps the capping layer 120. In detail, at least a portion of the connecting portion 130a, 130b overlaps the capping layer 120.

The connecting portion 130a, 130b may include a source connecting portion 130a and a drain connecting portion 130b. The source connecting portion 130a and the drain connecting portion 130b are spaced apart from each other, with a channel portion 130n and an offset portion 130s, 130t being therebetween.

According to one embodiment of the present disclosure, the source connecting portion 130a is spaced apart from the channel portion 130n and contacts the first offset portion 130s. In addition, the drain connecting portion 130b is spaced apart from the channel portion 130n and contacts the second offset portion 130t. The first offset portion 130s may be disposed between the channel portion 130n and the source connecting portion 130a, and the second offset portion 130t may be disposed between the channel portion 130n and the drain connecting portion 130b.

According to one embodiment of the present disclosure, the source connecting portion 130a and the drain connecting portion 130b do not overlap the gate electrode 150 and overlap the capping layer 120.

According to one embodiment of the present disclosure, the connecting portion 130a, 130b is a region where the oxide semiconductor material is conductorized. The connecting portion 130a, 130b may be referred to as a conductorized portion.

According to one embodiment of the present disclosure, a connecting portion 130a, 130b may be formed by a selective conductorization of the active layer 130. In detail, an oxide semiconductor material constituting the active layer 130 may be selectively conductorized to form a connecting portion 130a, 130b.

According to one embodiment of the present disclosure, the source connecting portion 130a and the drain connecting portion 130b are formed by selective conductorization of the active layer 130. For example, the source connecting portion 130a and the drain connecting portion 130b may be formed by selectively conductorizing an oxide semiconductor material constituting the active layer 130. The oxide semiconductor material constituting the active layer 130 may be selectively conductorized to form the source connecting portion 130a and the drain connecting portion 130b. According to one embodiment of the present disclosure, the conductorization may also be referred to as metallization.

According to one embodiment of the present disclosure, selective conductorization refers to improving the electrical conductivity of a selected portion of the active layer 130 or imparting electrical conductivity to the selected portion. A portion of the active layer 130 that is selectively conductorized has excellent electrical conductivity and thus may function as a wiring portion.

According to one embodiment of the present disclosure, for example, a portion of the active layer 130 that overlaps with the capping layer 120 may be selectively conductorized. In detail, in a region that overlaps with the capping layer 120, hydrogen contained in the gate insulating layer 140 moves to the active layer 130 instead of being released to the outside, so that the active layer 130 may be conductorized.

In the region overlapping with the capping layer 120, hydrogen included in the gate insulating layer 140 cannot be released to the outside and moves to the active layer 130. The hydrogen that has moved to the active layer 130 causes oxygen vacancies Vo in the region overlapping with the capping layer 120. Due to the oxygen vacancies Vo, the carrier concentration in the region overlapping with the capping layer 120 among the active layer 130 increases. As a result, the region of the active layer 130 that overlaps with the capping layer 120 may be conductorized.

As a result of the conductorization, the connecting portion 130a, 130b may have electrical properties similar to conductors. In detail, the source connecting portion 130a and the drain connecting portion 130b may each have electrical properties similar to metals.

According to one embodiment of the present disclosure, the active layer 130 may be selectively conductorized without doping or plasma treatment. Therefore, a conductorization process such as doping or plasma treatment for the active layer 130 may be omitted. Since an independent conductorization process is omitted, a thin film transistor 100 according to one embodiment of the present disclosure may be manufactured without the need for a separate facility for the conductorization process.

A gate insulating layer 140 is disposed on the active layer 130.

According to one embodiment of the present disclosure, the gate insulating layer 140 may be disposed to cover the entire upper surface of the active layer 130. Referring to FIG. 2, the gate insulating layer 140 may be disposed to cover the entire upper surface of the substrate 110.

The gate insulating layer 140 may be made of an insulating material containing hydrogen H. For example, a material for forming the gate insulating layer 140 may contain hydrogen H.

According to one embodiment of the present disclosure, the gate insulating layer 140 may include hydrogen H. Selective conductorization to the active layer 130 may be achieved by hydrogen H included in the gate insulating layer 140.

The gate insulating layer 140 may include, for example, at least one of silicon oxide SiOx, silicon nitride SiNx, and aluminum oxide AlOx.

Silicon oxide SiOx may be formed under conditions including silane SiH4 and oxygen O2. Therefore, the gate insulating layer 140 including silicon oxide SiOx may include hydrogen H.

Silicon nitride SiNx may be formed under conditions including silane SiH4, ammonia NH3, and oxygen O2. Therefore, the gate insulating layer 140 including silicon nitride SiNx may include hydrogen H.

Aluminum oxide AlOx may be formed under conditions including an aluminum compound and a hydroxyl group OH or moisture H2O. Accordingly, the gate insulating layer 140 including aluminum oxide AlOx may include hydrogen H.

However, one embodiment of the present disclosure is not limited thereto, and other known insulating materials containing hydrogen H may be applied to the gate insulating layer 140.

A capping layer 120 is disposed on the gate insulating layer 140.

The capping layer 120 may block hydrogen H. The capping layer 120 may act as a blocking film that blocks the movement of hydrogen. In addition, the emission or leakage of hydrogen in an area may be blocked by the capping layer 120. For example, the emission or movement of hydrogen toward the capping layer 120 may be blocked by the capping layer 120.

As the movement or leakage of hydrogen H is blocked by the capping layer 120, hydrogen H included in the gate insulating layer 140 may move to a specific region of the active layer 130. For example, hydrogen H included in the gate insulating layer 140 may move to a direction opposite to the capping layer 120. Selective conductorization for the active layer 130 may be achieved by hydrogen H whose movement is blocked by the capping layer 120.

The capping layer 120 may be made of a material capable of blocking hydrogen H. For example, the capping layer 120 may include at least one of an oxide semiconductor material and a metal oxide. In addition, according to one embodiment of the present disclosure, the capping layer 120 may have excellent chemical stability.

For example, the capping layer 120 may be formed of an oxide semiconductor material containing an excess of oxygen. The oxide semiconductor material applied to the capping layer 120 may be in a stoichiometrically stable oxide state.

The capping layer 120 may include an oxide semiconductor material, and the oxide semiconductor material included in the capping layer 120 may include oxygen at 50 atomic % (at %) or more based on the total number of atoms in the capping layer 120.

Additionally, the capping layer 120 may include a metal oxide. The capping layer 120 includes metal atoms and oxygen atoms. According to one embodiment of the present disclosure, the capping layer 120 may include a stoichiometrically stable oxide.

The metal oxide included in the capping layer 120 may include at least one of aluminum (Al), tungsten (W), titanium (Ti), chromium (Cr), vanadium (V), and manganese (Mn). According to one embodiment of the present disclosure, the capping layer 120 may include at least one of an aluminum (Al)-based oxide, a tungsten (W)-based oxide, a titanium (Ti)-based oxide, a chromium (Cr)-based oxide, a vanadium (V)-based oxide, and a manganese (Mn)-based oxide.

The capping layer 120 may cover a part of the active layer 130. Referring to FIGS. 1 and 2, a part of the active layer 130 overlaps with the capping layer 120, and another part of the active layer 130 does not overlap with the capping layer 120.

According to one embodiment of the present disclosure, there is no contact hole between the capping layer 120 and the active layer 130. In detail, in a region where the active layer 130 and the capping layer 120 overlap, the entire region between the active layer 130 and the capping layer 120 may be filled with the gate insulating layer 140. In addition, the capping layer 120 does not overlap the channel portion 130n.

When a contact hole is formed in the gate insulating layer 140, hydrogen around the contact hole can be removed by being released from the gate insulating layer 140. In this case, conductorization of the active layer 130 by hydrogen may be impossible.

According to one embodiment of the present disclosure, since there is no contact hole between the capping layer 120 and the active layer 130, a contact hole is not formed in the gate insulating layer 140 located under the capping layer 120 during the manufacturing process of the thin film transistor 100. Accordingly, hydrogen is not removed from the portion of the gate insulating layer 140 under the capping layer 120, and hydrogen is preserved therein. Accordingly, selective conductorization by hydrogen is possible.

Referring to FIGS. 1 and 2, the capping layer 120 may include a first capping layer 121 and a second capping layer 122. The first capping layer 121 overlaps the source connecting portion 130a. The second capping layer 122 overlaps the drain connecting portion 130b.

The active layer 130 may be selectively conductorized by the hydrogen under the first capping layer 121 to form a source connection 130a. The active layer 130 may be selectively conductorized by the hydrogen under the second capping layer 122 to form a drain connection 130b.

According to one embodiment of the present disclosure, the capping layer 120 may have a thickness of 10 nm to 300 nm. When the thickness of the capping layer 120 is less than 10 nm, the capping layer 120 may not sufficiently block hydrogen. In addition, when the thickness of the capping layer 120 is designed to be less than 10 nm, the capping layer 120 may be easily damaged and the mechanical stability may be deteriorated.

On the other hand, when the thickness of the capping layer 120 exceeds 300 nm, the capping layer 120 may protrude beyond the gate electrode 150 or the thickness of the thin film transistor 100 may become thicker.

In detail, the capping layer 120 may have a thickness of 10 nm to 200 nm or may have a thickness of 20 nm to 200 nm. In addition, the capping layer 120 may have a thickness of 10 nm to 100 nm or may have a thickness of 10 nm to 50 nm, or may have a thickness of 20 nm to 40 nm, or may have a thickness of 25 nm to 35 nm.

According to one embodiment of the present disclosure, a gate electrode 150 is disposed on a gate insulating layer 140. The gate electrode 150 is spaced apart from the active layer 130 and at least partially overlaps the active layer 130. The gate electrode 150 overlaps the channel portion 130n of the active layer 130.

In addition, the gate electrode 150 is disposed spaced apart from the capping layer 120.

The gate electrode 150 may include at least one of an aluminum-based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 150 may also have a multilayer structure including at least two conductive layers having different physical properties.

According to one embodiment of the present disclosure, the gate electrode 150 and the capping layer 120 are each formed by separate processes. Therefore, according to one embodiment of the present disclosure, the gate electrode 150 and the capping layer 120 may be designed to have different etching characteristics.

According to one embodiment of the present disclosure, the gate electrode 150 and the capping layer 120 may include different materials. For example, the capping layer 120 may include a material different from the material included in the gate electrode 150. As a result, the capping layer 120 may not be etched during the patterning process of the gate electrode 150.

An interlayer insulating layer 170 may be disposed on the capping layer 120 and the gate electrode 150. The interlayer insulating layer 170 is an insulating layer made of an insulating material. The interlayer insulating layer 170 may be made of an organic material, an inorganic material, or a laminate of an organic material layer and an inorganic material layer.

A source electrode 161 and a drain electrode 162 are disposed on an interlayer insulating layer 170. The source electrode 161 and the drain electrode 162 are spaced apart from each other and are connected to an active layer 130 respectively. Each of the source electrode 161 and the drain electrode 162 may be connected to the active layer 130 through a contact hole CH1, CH2 penetrating the interlayer insulating layer 170.

The source electrode 161 and the drain electrode 162 may each include at least one of molybdenum (Mo), aluminum (Al), chromium (Cr), gold (Au), titanium (Ti), nickel (Ni), neodymium (Nd), copper (Cu), and alloys thereof. The source electrode 161 and the drain electrode 162 may each be formed of a single layer made of a metal or a metal alloy of metals or may be formed of multilayer structure having two or more layers.

According to one embodiment of the present disclosure, at least one of the source electrode 161 and the drain electrode 162 may be in contact with the capping layer 120.

Referring to FIG. 2, the source electrode 161 may contact the first capping layer 121. In addition, the source electrode 161 may contact the source connecting portion 130a. The source electrode 161 may contact a side surface of the first capping layer 121. The source electrode 161 may contact a side surface of the first capping layer 121 opposite to the gate electrode 150. The source electrode 161 may contact an upper surface of the first capping layer 121.

According to one embodiment of the present disclosure, in the process of forming the first contact hole CH1 for connecting the source electrode 161 and the source connecting portion 130a, a part of the active layer 130 may be conductorized. In detail, by the process of forming the first contact hole CH1, a portion of the active layer 130 exposed by the first contact hole CH1 and a portion the active layer 130 around the first contact hole CH1 may be selectively conductorized. In order for stable electrical connection, a region of the active layer 130 overlapping the first capping layer 121 and a region of the active layer 130 where the first contact hole CH1 is formed may be disposed close to each other or may be made to contact each other.

In order for stable electrical connection, the first contact hole CH1 may be formed as close as possible to the first capping layer 121. According to one embodiment of the present disclosure, in order to secure the stability of the electrical connection, the first contact hole CH1 may be formed so that a side surface of the first capping layer 121 is exposed. As a result, the source electrode 161 filled in the first contact hole CH1 may contact the first capping layer 121.

Referring to FIG. 2, the drain electrode 162 may contact the second capping layer 122. In addition, the drain electrode 162 may contact the drain connecting portion 130b. The drain electrode 162 may contact a side surface of the second capping layer 122. The drain electrode 162 may contact a side surface of the second capping layer 122 opposite to the gate electrode 150. The drain electrode 162 may contact an upper surface of the second capping layer 122.

According to one embodiment of the present disclosure, in the process of forming the second contact hole CH2 for connecting the drain electrode 162 and the drain connecting portion 130b, a part of the active layer 130 may be conductorized. In detail, by the process of forming the second contact hole CH2, a portion of the active layer 130 exposed by the second contact hole CH2 and a portion of the active layer 130 around the second contact hole CH2 may be selectively conductorized.

In order for stable electrical connection, the second contact hole CH2 may be formed as close as possible to the second capping layer 122. According to one embodiment of the present disclosure, in order for stable electrical connection, the second contact hole CH2 may be formed so that a side surface of the second capping layer 122 is exposed. As a result, the drain electrode 162 filled in the second contact hole CH2 may contact the second capping layer 122.

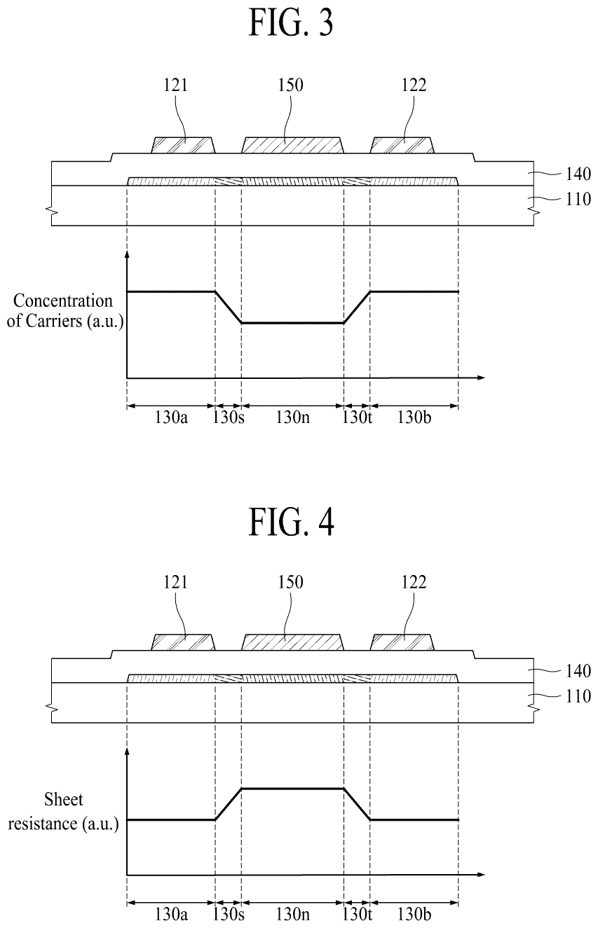

FIG. 3 is a graph explaining the carrier concentration distribution of the active layer 130.

Referring to FIG. 3, the offset portion 130s, 130t of the present disclosure has a higher carrier concentration than the channel portion 130n and a lower carrier concentration than the connecting portion 130a, 130b. In addition, the carrier concentration of the offset portion 130s, 130t increases in the direction from the channel portion 130n toward the connecting portion 130a, 130b.

In the region overlapping with the capping layer 120, hydrogen included in the gate insulating layer 140 moves to the active layer 130, causing oxygen vacancy Vo, so that the carrier concentration in the region overlapping with the capping layer 120 in the active layer 130 increases. As a result, the connecting portions 130a, 130b overlapping with the capping layer 120 have high carrier concentrations.

In addition, hydrogen may diffuse in a direction from the connecting portions 130a, 130b toward the channel portion 130n. However, there is a restriction to the amount of hydrogen that may diffuse, and thus the amount of hydrogen that can diffuse will gradually decrease in the direction from the connecting portions 130a, 130b toward the channel portion 130n. By this diffusion of hydrogen as described above, the offset portions 130s, 130t are formed.

Since the amount of hydrogen diffusion gradually decreases in the direction from the connecting portions 130a, 130b toward the channel portion 130n, the carrier concentration decreases in the direction from the connecting portions 130a, 130b toward the channel portion 130n. As a result, in the offset portions 130s, 130t, a pattern of increasing carrier concentration appears in the direction from the channel portion 130n toward the connecting portions 130a, 130b.

Referring to FIG. 3, the offset portions 130s, 130t may have a gradient of carrier concentration that gradually increases along the direction from the channel portion CN1 toward the connecting portions 130a, 130b.

Depending on the position of the capping layer 120, hydrogen may not diffuse or may hardly diffuse into the channel portion 130n. As a result, oxygen vacancy Vo may not occur in the channel portion 130n or may be suppressed. Accordingly, the channel portion 130n has a lower carrier concentration than the connecting portions 130a, 130b and the offset portions 130s, 130t.

According to one embodiment of the present disclosure, the length of the offset portion 130s, 130t may be adjusted by adjusting the positions of the gate electrode 150 and the capping layer 120. As a result, the length of the channel portion 130n may be effectively controlled.

In detail, according to one embodiment of the present disclosure, the capping layer 120 may be formed by patterning using a photolithography method. Therefore, the size and position of the capping layer 120 may be precisely adjusted. As a result, the conductorized portion formed by the capping layer 120 may be controlled, and the positions and sizes of the connecting portions 130a, 130b and the offset portions 130s, 130t may be effectively adjusted.

On the other hand, when conductorization is accomplished by doping or plasma treatment, it is difficult to control the size and length of the conducting portion because it is not easy to control the diffusion of the dopant or the influence range of the plasma. Therefore, when conductorization is accomplished by doping or plasma treatment, strict process management is required to control the size and length of the conducting portion.

Thus, according to one embodiment of the present disclosure, the length of the channel portion 130n and the offset portion 130s, 130t may be effectively controlled in a simpler manner compared to a doping or plasma treatment method.

FIG. 4 is a graph explaining the distribution of sheet resistance for each region of the active layer 130.

In detail, FIG. 4 shows the sheet resistance of each region of the active layer 130 in the turn-off state of the thin film transistor 100.

Since the channel portion 130n has a lower carrier concentration than the connecting portions 130a, 130b and the offset portions 130s, 130t, the channel portion 130n has a higher surface resistance than the connecting portions 130a, 130b and the offset portions 130s, 130t when the thin film transistor 100 is off.

Since the connecting portions 130a, 130b, which are conductorized portions, have a high carrier concentration, and thus have a low resistance.

In the offset portion 130s, 130t, since the carrier concentration increases in the direction from the channel portion 130n toward the connecting portion 130a, 130b, the surface resistance decreases in the direction from the channel portion 130n toward the connecting portion 130a, 130b.

According to one embodiment of the present disclosure, by adjusting the position of the capping layer 120, the effective channel length may be stably secured by suppressing the inflow of hydrogen into the channel portion 130n.

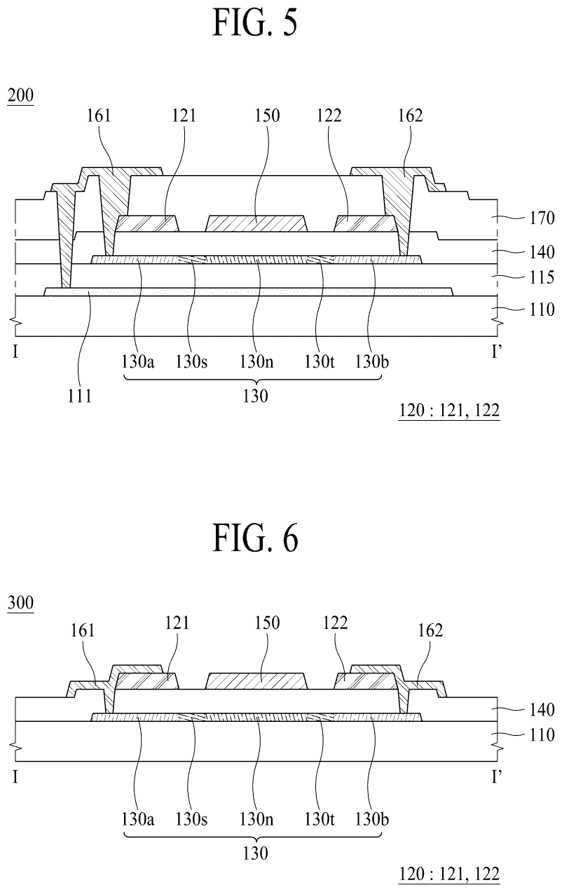

FIG. 5 is a cross-sectional view of a thin film transistor 200 according to another embodiment of the present disclosure.

Hereinafter, to avoid redundancy, descriptions of components already described are omitted, or components already described are briefly described.

Referring to FIG. 5, a light-shielding layer 111 may be disposed on a substrate 110. The light-shielding layer 111 has light-shielding properties. The light-shielding layer 111 may block light incident from the substrate 110 and protect the channel portion 130n of the active layer 130.

The light-shielding layer 111 may be made of a material having light shielding properties. The light-shielding layer 111 may include at least one of an aluminum-based metal such as aluminum (Al) or an aluminum alloy, a molybdenum-based metal such as molybdenum (Mo) or a molybdenum alloy, chromium (Cr), tantalum (Ta), neodymium (Nd), titanium (Ti), and iron (Fe).

According to one embodiment of the present disclosure, the light-shielding layer 111 may have electrical conductivity. The light-shielding layer 111 may be electrically connected to either the source electrode 161 or the drain electrode 162. Referring to FIG. 5, the light-shielding layer 111 may be connected to the source electrode 161.

A buffer layer 115 is disposed on the light-shielding layer 111. The buffer layer 115 covers the upper surface of the substrate 110 and the upper surface of the light-shielding layer 111. The buffer layer 115 has insulating properties and protects the active layer 130.

Referring to FIG. 5, the active layer 130 may be disposed on the buffer layer 115.

FIG. 6 is a cross-sectional view of a thin film transistor 300 according to another embodiment of the present disclosure.

According to another embodiment of the present disclosure, the source electrode 161 and the drain electrode 162 are each formed on the capping layer 120 and may contact the capping layer 120.

Referring to FIG. 6, the source electrode 161 may be disposed on the first capping layer 121 and may contact the first capping layer 121. The source electrode 161 may contact the upper surface and side surface of the first capping layer 121.

Referring to FIG. 6, the drain electrode 162 may be disposed on the second capping layer 122 and may contact the second capping layer 122. The drain electrode 162 may contact the upper surface and side surfaces of the second capping layer 122.

Referring to FIG. 6, a portion of the source electrode 161 and a portion of the drain electrode 162 may be disposed on the gate insulating layer 140. Referring to FIG. 6, the gate insulating layer 140 may cover the entire upper portion of the active layer 130.

According to one embodiment of the present disclosure, as illustrated in FIG. 6, a portion of the source electrode 161 and a portion of the drain electrode 162 may be disposed on the same layer as the gate electrode 150.

According to another embodiment of the present disclosure, the source electrode 161 and the drain electrode 162 may be made of the same material as the gate electrode 150. The source electrode 161 and the drain electrode 162 may be formed together with the gate electrode 150 by a same process as the process for forming the gate electrode 150.

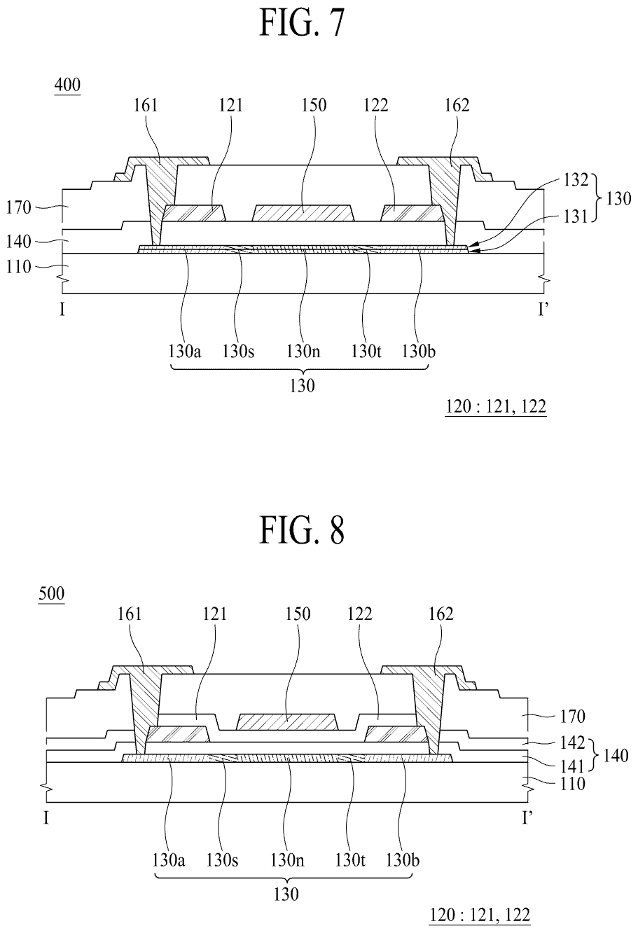

FIG. 7 is a cross-sectional view of a thin film transistor 400 according to another embodiment of the present disclosure.

Referring to FIG. 7, the active layer 130 may include a first oxide semiconductor layer 131 and a second oxide semiconductor layer 132 on the first oxide semiconductor layer 131.

The first oxide semiconductor layer 131 may serve as a support layer supporting the second oxide semiconductor layer 132. The second oxide semiconductor layer 132 may serve as a main channel layer.

The first oxide semiconductor layer 131 serving as a support layer may have good film stability and mechanical stability. The first oxide semiconductor layer 131 may include, for example, at least one of an IGO (InGaO)-based, IGZO (InGaZnO)-based, IGZTO (InGaZnSnO)-based, GZTO (GaZnSnO)-based, GZO (GaZnO)-based, and GO (GaO)-based oxide semiconductor material. However, one embodiment of the present disclosure is not limited thereto, and the first oxide semiconductor layer 131 may be formed of other oxide semiconductor materials known in the art.

The second oxide semiconductor layer 132 may include at least one of oxide semiconductor materials, such as IZO (InZnO)-based, FIZO (FeInZnO)-based, TO (SnO)-based, IGO (InGaO)-based, ITO (InSnO)-based, IGZO (InGaZnO)-based, IGZTO (InGaZnSnO)-based, GZTO (GaZnSnO)-based, ITZO (InSnZnO)-based, and IO (InO)-based, for example. However, one embodiment of the present disclosure is not limited thereto, and the second oxide semiconductor layer 132 may be formed by other oxide semiconductor materials known in the art.

FIG. 8 is a cross-sectional view of a thin film transistor 500 according to another embodiment of the present disclosure.

According to another embodiment of the present disclosure, the gate insulating layer 140 may have a multilayer structure.

Referring to FIG. 8, the gate insulating layer 140 may include a first gate insulating layer 141 and a second gate insulating layer 142 on the first gate insulating layer 141.

When the gate insulating layer 140 has a multilayer structure, the capping layer 120 may be disposed on a different layer from the gate electrode 150. When the capping layer 120 and the gate electrode 150 are disposed on different layers, the capping layer 120 may be disposed closer to the active layer 130 than the gate electrode 150.

According to another embodiment of the present disclosure, the capping layer 120 may be disposed on the first gate insulating layer 141, and the gate electrode 140 may be disposed on the second gate insulating layer 142.

According to another embodiment of the present disclosure, the connecting portions 130a, 130b may be conductorized by the capping layer 120. On the other hand, the channel portion 130n is not conductorized. In order to make the connecting portions 130a, 130b conductorized and the channel portion 130n not be conductorized, the capping layer 120 is formed before the gate electrode 150 to make the connecting portions 130a, 130b conductorized. The gate electrode 150 may be formed after the connecting portions 130a, 130b are conductorized.

Therefore, according to another embodiment of the present disclosure, a capping layer 120 may be formed on a first gate insulating layer 141 to selectively conductorize the active layer 130, then a second gate insulating layer 142 may be formed, and a gate electrode 140 may be formed on the second gate insulating layer 142.

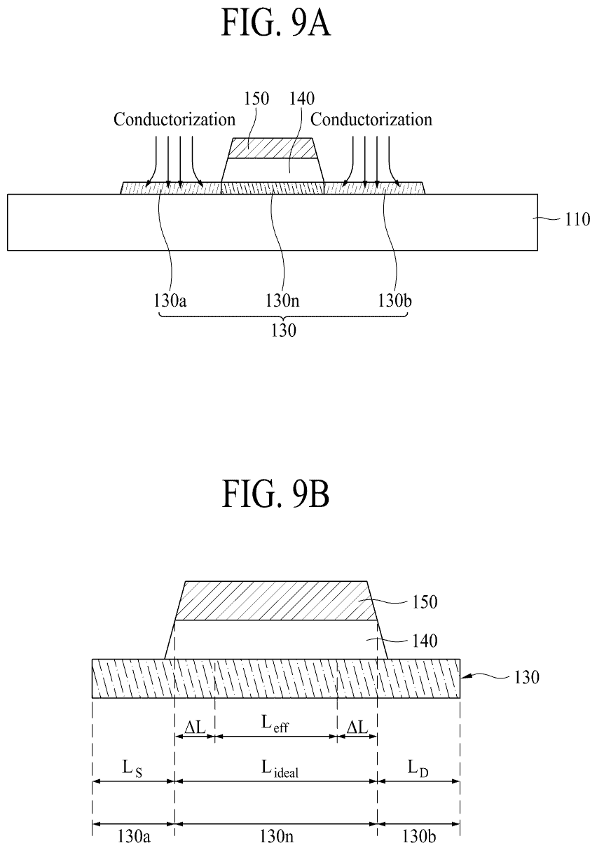

FIG. 9A is a schematic diagram explaining a conventional conductor method, and FIG. 9B is a schematic diagram explaining the conductorization penetration depth ΔL.

Below, with reference to FIGS. 9A and 9B, the conductor and effective channel length are described.

Referring to FIG. 9A, selective conductivity for the active layer 130 may be achieved using the gate electrode 150 as a mask. For example, conductorization may be achieved by dry etching, plasma treatment, or doping.

According to the method illustrated in FIG. 9A, selective conductorization for the active layer 130 may be performed so that the first connecting portion 130a and the second connecting portion 130b may be formed. In this process, the channel portion 130n may unintentionally be partially conductorized. For example, an area adjacent to the first connecting portion 130a or the second connecting portion 130b in the channel portions 130n may be conductorized. However, in the conductorization process, it is not easy to control the degree of conductorization of the edge of the channel portion 130n.

A length or a distance of a portion of the channel portion 130n that is conductorized during the conductorization process may be referred to as the conductorization penetration depth ΔL.

FIG. 9B is a schematic diagram explaining the conductorization penetration depth ΔL.

In FIG. 9B, the length of the channel portion 130n overlapping the gate electrode 150 in the active layers 130 is indicated as “L_{ideal}”. “L_{ideal}” in FIG. 9B may be referred to as a length of the ideal channel portion 130n. In FIG. 9B, “L_{S}” refers to a length of the first connecting portion 130a, and “L_{D}”refers to a length of the second connecting portion 130b.

In the selective conductorization process to the active layer 130, a part of the channel portion 130n is conductorized, and the conductorized portion does not function as a channel. Therefore, it is difficult for the region indicated by “ΔL”, which is a conductorized portion of the channel portion 130n in FIG. 9B, to function as a channel.

In addition, the length of the region of the channel portion 130n that is not conductorized and may effectively function as a channel is called the effective channel length Leff. As the conductorization penetration depth ΔL increases, the effective channel length Leff decreases.

In order for a thin film transistor to perform a switching function, the effective channel length Leff should be maintained at a predetermined value or more. However, if the degree of conductorization at the edge of the channel portion 130n cannot be controlled, it is difficult to design the width of the channel portion 130n. For example, when considering a design error margin, the width of the channel portion 130n must be designed to be wider than a required width in order to secure a predetermined effective channel length Leff. In this case, the size of the thin film transistor may increase, and it is difficult to miniaturize and integrate the device.

On the other hand, according to one embodiment of the present disclosure, the conductorized portion and its adjacent portion may be controlled by using the capping layer 120. In detail, according to one embodiment of the present disclosure, the length of the connecting portion 130a, 130b and the length of the offset portion 130s, 130d may be controlled by using the capping layer 120.

In particular, since the capping layer 120 may be formed by a photolithography method, the size and position of the capping layer 120 may be precisely adjusted. As a result, control over the conductorized portion, which is formed by the capping layer 120, is possible, and the positions and sizes of the connecting portions 130a, 130b and the offset portions 130s, 130t may be effectively controlled.

In this way, according to embodiments of the present disclosure, selective conductorization for the active layer 130 may be easily performed by arranging the capping layer 120 on the gate insulating layer 140. According to one embodiment of the present disclosure, compared to doping or plasma treatment methods, the lengths of the channel portion 130n and the offset portions 130s, 130t may be effectively controlled in a simpler manner.

According to embodiments of the present disclosure, since selective conductorization for the active layer 130 is possible by the capping layer 120 disposed on the gate insulating layer 140, a conductorization process such as doping or plasma treatment for the active layer 130 may be omitted. Since the conductorization process is omitted, a thin film transistor 100, 200, 300, 400, 500 according to embodiments of the present disclosure may be manufactured without a separate facility for the conductorization process.

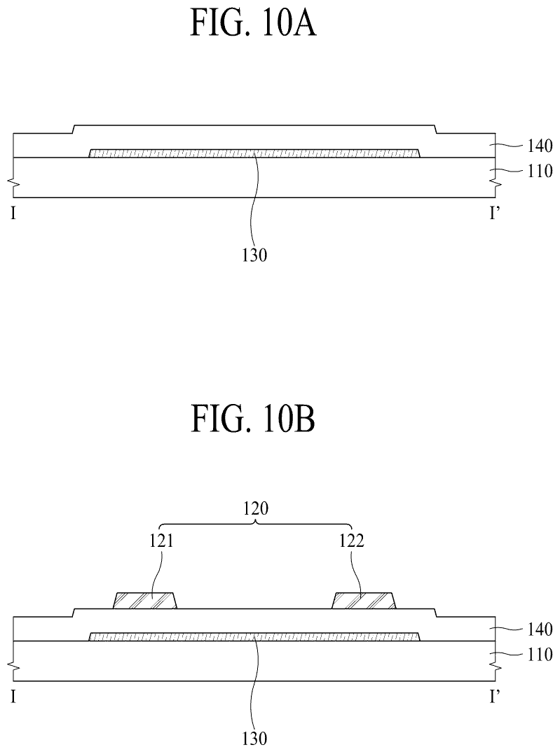

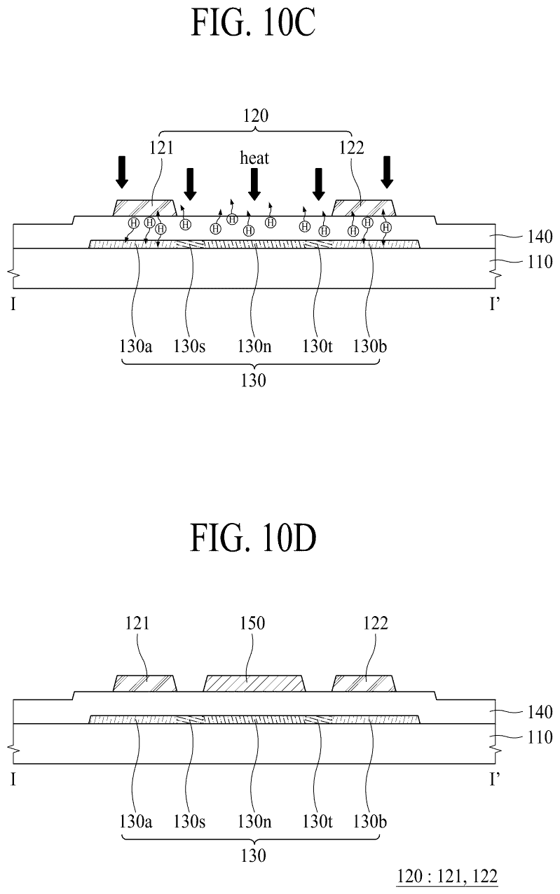

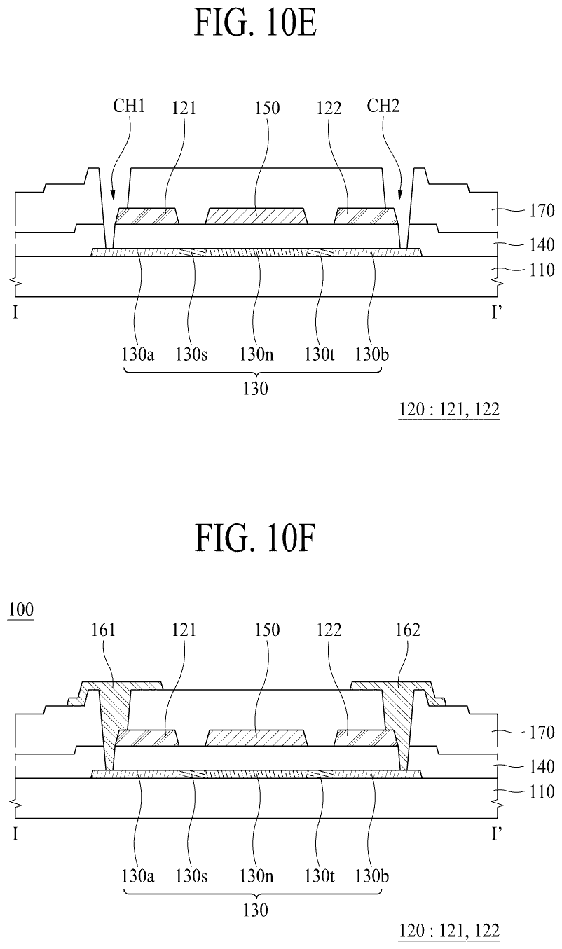

FIGS. 10A to 10F are schematic cross-sectional views illustrating a method for manufacturing a thin film transistor 100 according to another embodiment of the present disclosure.

A method for manufacturing a thin film transistor 100 according to another embodiment of the present disclosure includes a step of forming an active layer 130 on a substrate 110, a step of forming a gate insulating layer 140 on the active layer 130, a step of forming a capping layer 120 on the gate insulating layer 140, a step of heat treating the gate insulating layer 140, and a step of forming a gate electrode 150 on the heat treated gate insulating layer 140.

First, referring to FIG. 10A, an active layer 130 is formed on a substrate 110. Next, a gate insulating layer 140 is formed on the active layer 130.

Referring to FIG. 10B, a capping layer 120 is formed on a gate insulating layer 140. The capping layer 120 may include a first capping layer 121 and a second capping layer 122. The first capping layer 121 and the second capping layer 122 are formed on the gate insulating layer 140 while being spaced apart from each other.

Referring to FIG. 10C, the gate insulating layer 140 is heat-treated. The heat treatment for the gate insulating layer 140 is performed in a state where a capping layer 120 is formed on the gate insulating layer 140. By the heat treatment for the gate insulating layer 140, heat treated gate insulating layer 140 is formed.

The connecting portions 130a, 130b and offset portions 130s, 130t of the active layer 130 are formed by the heat treatment of the gate insulating layer 140.

During the heat treatment process for the gate insulating layer 140, hydrogen H contained in the gate insulating layer 140 may be activated, and the mobility of hydrogen H becomes active.

The heat treatment temperature may range from 60° C. to 450° C. Specifically, the heat treatment may be performed at a temperature of from 100° C. to 400° C. In detail, the heat treatment may be performed at a temperature of from 200° C. to 350° C.

By heat treatment of the gate insulating layer 140, hydrogen H included in the gate insulating layer 140 may be released to the outside. Meanwhile, in a region overlapping the gate insulating layer 140 and the capping layer 120, hydrogen included in the gate insulating layer 140 may move to the active layer 130 without being released to the outside.

Hydrogen that has moved from the region of gate insulating layer 140 overlapping the capping layer 120 to the active layer 130 causes oxygen vacancy Vo. Due to the oxygen vacancy Vo, the region of the active layer 130 overlapping the capping layer 120 can be conductorized. A connection 130a, 130b can be formed in the region of the active layer 130 overlapping the capping layer 120.

In addition, hydrogen can diffuse in a direction from the connecting portion 130a, 130b toward the channel portion 130n. An offset portion 130s, 130t can be formed by this diffusion of hydrogen.

Referring to FIG. 10D, a gate electrode 150 is formed on a gate insulating layer 140. The gate electrode 150 is formed to at least partially overlap with the active layer 130. The gate electrode 150 overlaps with the channel portion 130n of the active layer 130.

Referring to FIG. 10E, an interlayer insulating layer 170 is formed on the capping layer 120 and the gate electrode 150. Next, a contact hole CH1, CH2 penetrating the interlayer insulating layer 170 and the gate insulating layer may be formed. The contact hole CH1, CH2 includes a first contact hole CH1 and a second contact hole CH2.

The first contact hole CH1 may be formed as close as possible to the first capping layer 121. According to one embodiment of the present disclosure, in order to secure stability of electrical connection, the first contact hole CH1 may be formed such that a side surface of the first capping layer 121 is exposed. As a result, the source electrode 161 filled in the first contact hole CH1 may come into contact with the first capping layer 121.

The second contact hole CH2 may be formed as close as possible to the second capping layer 122. According to one embodiment of the present disclosure, in order to secure stability of electrical connection, the second contact hole CH2 may be formed so that a side surface of the second capping layer 122 is exposed. As a result, the drain electrode 162 filled in the second contact hole CH2 may come into contact with the second capping layer 122.

Referring to FIG. 10F, a source electrode 161 and a drain electrode 162 are formed on an interlayer insulating layer 170. The source electrode 161 and the drain electrode 162 are spaced apart from each other and each is connected to an active layer 130.

The source electrode 161 may contact the first capping layer 121 and the source connecting portion 130a through the first contact hole CH1.

The drain electrode 162 may contact the second capping layer 122 and the drain connecting portion 130b through the second contact hole CH2.

By this process, a thin film transistor 100 according to one embodiment of the present disclosure may be formed.

Another embodiment of the present disclosure provides a display device including the thin film transistor 100, 200, 300, 400, 500 described above.

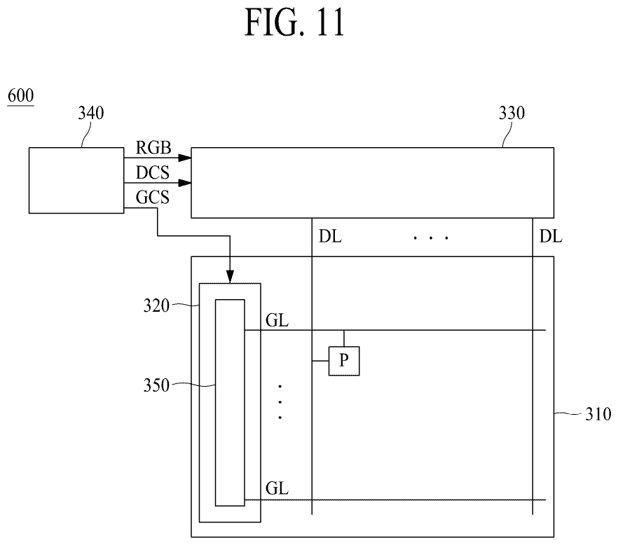

FIG. 11 is a schematic diagram of a display device 600 according to another embodiment of the present disclosure.

A display device 600 according to another embodiment of the present disclosure includes a display panel 310, a gate driver 320, a data driver 330, and a control unit 340 (e.g., a control circuit), as illustrated in FIG. 11.

Gate lines GL and data lines DL are disposed on the display panel 310, and pixels P are disposed in the intersection area of the gate lines GL and data lines DL. An image is displayed by driving the pixels P.

The control unit 340 is configured to control the gate driver 320 and the data driver 330.

The control unit 340 is configured to output a gate control signal GCS for controlling the gate driver 320 and a data control signal DCS for controlling the data driver 330 using a signal supplied from an external system. In addition, the control unit 340 is configured to sample input image data input from an external system, rearranges it, and supplies rearranged digital image data RGB to the data driver 330.

The gate control signal GCS includes a gate start pulse GSP, a gate shift clock GSC, a gate output enable signal GOE, a start signal Vst, and a gate clock GCLK. In addition, the gate control signal GCS may include control signals for controlling the shift register 350.

Data control signals DCS include source start pulse SSP, source shift clock signal SSC, source output enable signal SOE, and polarity control signal POL.

The data driver 330 supplies data voltage to the data lines DL of the display panel 310. Specifically, the data driver 330 converts image data RGB input from the control unit 340 into analog data voltage and supplies the data voltage to the data lines DL.

The gate driver 320 may include a shift register 350.

The shift register 350 sequentially supplies gate pulses to the gate lines GL for one frame using a start signal and a gate clock transmitted from the control unit 340. Here, one frame refers to a period during which one image is output through the display panel 310. The gate pulse has a turn-on voltage capable of turning on a switching element (thin film transistor) disposed in a pixel P.

In addition, the shift register 350 supplies a gate off signal capable of turning off the switching element to the gate line GL during the remaining period during which the gate pulse is not supplied during one frame. Hereinafter, the gate pulse and the gate off signal are collectively referred to as a scan signal SS or Scan.

According to one embodiment of the present disclosure, the gate driver 320 may be mounted on the substrate 110. In this way, a structure in which the gate driver 320 is directly mounted on the substrate 110 is called a Gate In Panel GIP structure. The gate driver 320 may include at least one of the thin film transistors 100, 200, 300, 400, 500 described above.

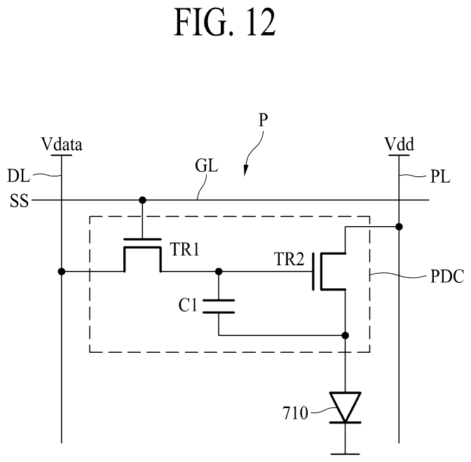

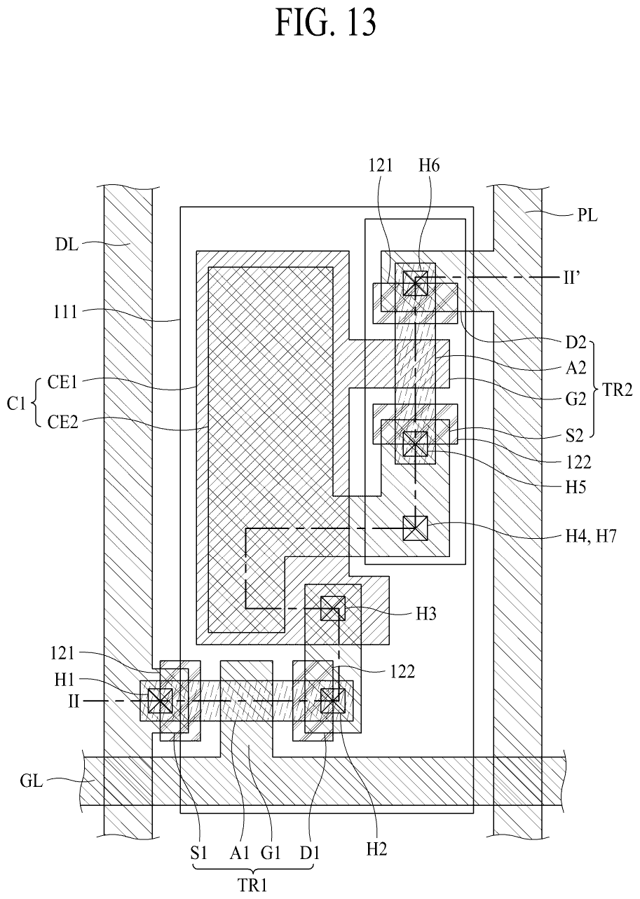

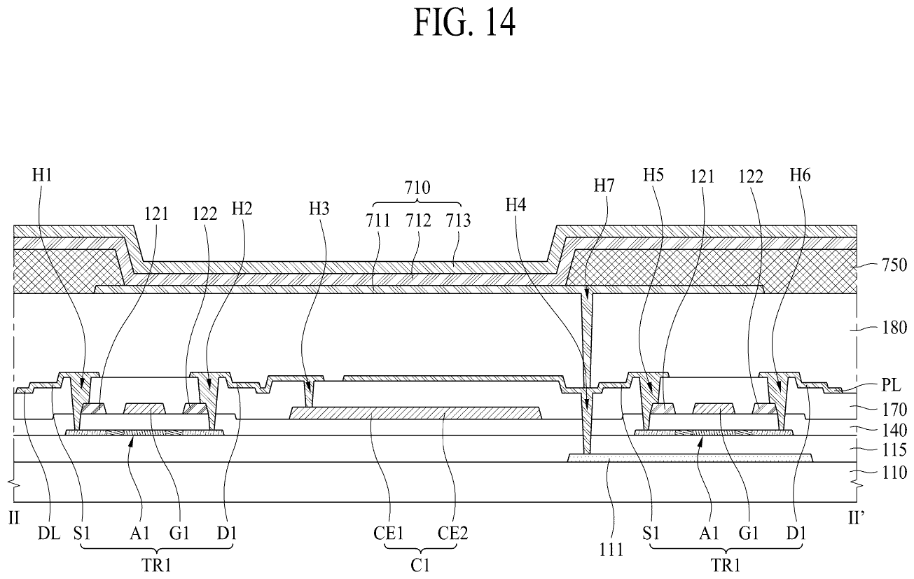

FIG. 12 is a circuit diagram for one pixel P of FIG. 11, FIG. 13 is a plan view for the pixel P of FIG. 12 according to one embodiment, and FIG. 14 is a cross-sectional view taken along line II-II′ of FIG. 13 according to one embodiment.

The circuit diagram of FIG. 12 is an equivalent circuit diagram for a pixel P of a display device 600 including an organic light-emitting diode OLED as a display element 710.

The pixel P includes a display element 710 and a pixel driver PDC that drives the display element 710.

The pixel driver PDC of FIG. 12 includes a first thin film transistor TR1 which is a switching transistor and a second thin film transistor TR2 which is a driving transistor.

A display device 600 according to another embodiment of the present disclosure may include at least one of the thin film transistors 100, 200, 300, 400, 500 described above. As the first thin film transistor TR1 or the second thin film transistor TR2 of FIG. 12, any one of the thin film transistors 100, 200, 300, 400, 500 described above may be used.

The first thin film transistor TR1 is connected to the gate line GL and the data line DL, and is turned on or off by the scan signal SS supplied through the gate line GL.

The data line DL provides a data voltage Vdata to the pixel driver PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light-emitting diode OLED, which is the display element 710.

When the first thin film transistor TR1 is turned on by a scan signal SS applied through the gate line GL from the gate driver 320, the data voltage Vdata supplied through the data line DL is supplied to the gate electrode G2 of the second thin film transistor TR2 connected to the display element 710. The data voltage Vdata is charged in the first capacitor C1 formed between the gate electrode G2 and the source electrode S2 of the second thin film transistor TR2. The first capacitor C1 is a storage capacitor Cst.

The amount of current supplied to the organic light-emitting diode OLED, which is a display element 710, through the second thin film transistor TR2 is controlled according to the data voltage Vdata, and accordingly, the gradation of light output from the display element 710 can be controlled.

Referring to FIG. 13 and FIG. 14, a first thin film transistor TR1 and a second thin film transistor TR2 are disposed on a substrate 110.

The substrate 110 may be made of glass or plastic. As the substrate 110, a plastic having flexible properties, for example, polyimide PI, may be used.

A light-shielding layer 111 may be disposed on the substrate 110. The light-shielding layer 111 may block light incident from the outside to protect the active layer A2.

Although a configuration in which a light-shielding layer 111 is disposed under the active layer A2 of the second thin film transistor TR2 is illustrated in FIGS. 13 and 14, another embodiment of the present disclosure is not limited thereto. A light-shielding layer 111 may also be disposed under the active layer A1 of the first thin film transistor TR1.

A buffer layer 115 is disposed on the light-shielding layer 111. The buffer layer 115 is made of an insulating material and protects the active layers A1, A2 from moisture or oxygen flowing in from the outside.

An active layer A1 of a first thin film transistor TR1 and an active layer A2 of a second thin film transistor TR2 are disposed on a buffer layer 115.

The active layers A1, A2 include an oxide semiconductor material. According to another embodiment of the present disclosure, the active layers A1, A2 are oxide semiconductor layers made of an oxide semiconductor material.

The gate insulating layer 140 is disposed on the active layers A1, A2. The gate insulating layer 140 has insulating properties and separates the active layers A1, A2 from the gate electrodes G1, G2. As illustrated in FIG. 14, the gate insulating layer 140 may not be patterned. However, another embodiment of the present disclosure is not limited thereto, and the gate insulating layer 140 may be patterned.

The capping layer 121, 122 is disposed on the gate insulating layer 140. The capping layer 121, 122 may cover a part of the active layer A1, A2.

Additionally, a gate electrode G1 of a first thin film transistor TR1 and a gate electrode G2 of a second thin film transistor TR2 are disposed on a gate insulating layer 140.

The gate electrode G1 of the first thin film transistor TR1 overlaps with the active layer A1 of the first thin film transistor TR1. The gate electrode G2 of the second thin film transistor TR2 overlaps with the active layer A2 of the second thin film transistor TR2.

Referring to FIGS. 13 and 14, the first capacitor electrode CE1 of the first capacitor C1 is disposed on the same layer as the gate electrodes G1, G2. The gate electrodes G1, G2 and the first capacitor electrode CE1 may be manufactured together by the same process using the same material.

An interlayer insulating layer 170 is disposed on the capping layer 121, 122, the gate electrode G1, G2, and the first capacitor electrode CE1.

A source electrode S1, S2 and a drain electrode D1, D2 are disposed on an interlayer insulating layer 170. According to one embodiment of the present disclosure, the source electrode S1, S2 and the drain electrode D1, D2 are distinguished only for convenience of explanation, and the source electrode S1, S2 and the drain electrode D1, D2 may be interchanged with each other. Accordingly, the source electrode S1, S2 may become the drain electrode D1, D2, and the drain electrode D1, D2 may become the source electrode S1, S2.

In addition, a data line DL and a driving power line PL are disposed on the interlayer insulating layer 170. The source electrode S1 of the first thin film transistor TR1 may be formed integrally with the data line DL. The drain electrode D2 of the second thin film transistor TR2 may be formed integrally with the driving power line PL.

According to one embodiment of the present disclosure, the source electrode S1 and the drain electrode D1 of the first thin film transistor TR1 are spaced apart from each other and are respectively connected to the active layer A1 of the first thin film transistor TR1. The source electrode S2 and the drain electrode D2 of the second thin film transistor TR2 are spaced apart from each other and are respectively connected to the active layer A2 of the second thin film transistor TR2.

Specifically, the source electrode S1 of the first thin film transistor TR1 contacts the source connection of the active layer A1 through the first contact hole H1.

The drain electrode D1 of the first thin film transistor TR1 contacts the drain connecting portion of the active layer A1 through the second contact hole H2 and is connected to the first capacitor electrode CE1 through the third contact hole H3.

The source electrode S2 of the second thin film transistor TR2 extends over the interlayer insulating layer 170, and a portion of it functions as a second capacitor electrode CE2. The first capacitor electrode CE1 and the second capacitor electrode CE2 overlap to form a first capacitor C1.

The source electrode S2 of the second thin film transistor TR2 contacts the light shielding layer 111 through the fourth contact hole H4 and contacts the source connection of the active layer A2 through the fifth contact hole H5.

The drain electrode D2 of the second thin film transistor TR2 contacts the drain connection of the active layer A2 through the sixth contact hole H6.

The first thin film transistor TR1 includes an active layer A1, a gate electrode G1, a source electrode S1, and a drain electrode D1, and acts as a switching transistor that controls the data voltage Vdata applied to the pixel driver PDC.

The second thin film transistor TR2 includes an active layer A2, a gate electrode G2, a source electrode S2, and a drain electrode D2, and acts as a driving transistor that controls the driving voltage Vdd applied to the display element 710.

A planarization layer 180 is disposed on the source electrodes S1, S2, the drain electrodes D1, D2, the data line DL, the driving power line PL, and the second capacitor electrode CE2. The planarization layer 180 planarizes the upper portions of the first thin film transistor TR1 and the second thin film transistor TR2 and protects the first thin film transistor TR1 and the second thin film transistor TR2.

A first electrode 711 of a display element 710 is disposed on a planarization layer 180. The first electrode 711 of the display element 710 is connected to a source electrode S2 of a second thin film transistor TR2 through a seventh contact hole H7 formed in the planarization layer 180.

A bank layer 750 is disposed at the edge of the first electrode 711. The bank layer 750 defines a light-emitting area of the display element 710.

An organic light-emitting layer 712 is disposed on a first electrode 711, and a second electrode 713 is disposed on the organic light-emitting layer 712. Accordingly, a display element 710 is completed. The display element 710 illustrated in FIG. 14 is an organic light-emitting diode OLED. Therefore, a display device 100 according to an embodiment of the present disclosure is an organic light-emitting display device.

A pixel driver PDC according to another embodiment of the present disclosure may be formed in various structures other than the structures described above. The pixel driver PDC may include, for example, three or more thin film transistors and two or more capacitors.

According to the present disclosure, the following advantageous effects may be obtained.

According to one embodiment of the present disclosure, hydrogen may be selectively supplied to an active layer using a capping layer. As a result, selective conductorization for the active layer is possible without a separate conductorization process.

According to one embodiment of the present disclosure, by adjusting the hydrogen supply position using the capping layer, the conductorization position of the active layer may be controlled. As a result, the distance between the channel portion and the conductorized portion may be adjusted, and the effective channel length may be stably secured.

According to one embodiment of the present disclosure, the capping layer does not completely surround the active layer, but covers only a portion of the active layer. Even when the capping layer is disposed, hydrogen contained in the gate insulating layer may be discharged to the outside, thereby preventing hydrogen from accumulating in the channel portion of the active layer.

In addition, according to one embodiment of the present disclosure, hydrogen flowing into the channel region of the active layer from a layer other than the gate insulating layer may be blocked by the capping layer and the gate electrode. Accordingly, the active layer may be protected by the capping layer and the gate electrode.

A thin film transistor according to one embodiment of the present disclosure including a capping layer has excellent reliability and stability with respect to hydrogen.

A display device according to one embodiment of the present disclosure includes a thin film transistor having excellent stability as described above. Therefore, the display device according to one embodiment of the present disclosure can exhibit stable display performance.

In addition to the effects mentioned above, other features and advantages of the present disclosure are described below or may be clearly understood by those skilled in the art to which the present disclosure pertains from such description and explanation.

The present disclosure described above is not limited to the above-described embodiments and the attached drawings, and it will be apparent to a person skilled in the art to which the present disclosure pertains that various substitutions, modifications, and changes are possible within a scope that does not depart from the technical details of the present disclosure.

What is claimed is:

1. A thin film transistor comprising:
an active layer;
a gate insulating layer on the active layer;
a gate electrode on the gate insulating layer; and
a capping layer on the gate insulating layer,
wherein the gate electrode and the capping layer are spaced apart from each other,
wherein a part of the active layer overlaps the gate electrode, and
wherein another part of the active layer overlaps the capping layer.

2. The thin film transistor of claim 1, the active layer comprising:
a channel portion overlapping the gate electrode;
an offset portion in contact with one side of the channel portion; and
a connecting portion spaced apart from the channel portion and in contact with the offset portion,
wherein the connecting portion overlaps the capping layer, and
wherein the offset portion is non-overlapping with the gate electrode and capping layer.

3. The thin film transistor of claim 2, wherein the connecting portion is an area in which an oxide semiconductor material is conductorized.

4. The thin film transistor of claim 2, wherein a carrier concentration of the offset portion is higher than a carrier concentration of the channel portion and lower than a carrier concentration of the connecting portion.

5. The thin film transistor of claim 2, wherein a carrier concentration of the offset portion increases along a direction from the channel portion toward the connecting portion.

6. The thin film transistor of claim 1, wherein the gate insulating layer comprises at least one of silicon oxide SiOx, silicon nitride SiNx, or aluminum oxide AlOx.

7. The thin film transistor of claim 1, wherein the capping layer comprises at least one of an oxide semiconductor material or a metal oxide.

8. The thin film transistor of claim 1, wherein an entire area between the active layer and capping layer is filled with the gate insulating layer, and the capping layer does not contact the active layer.

9. The thin film transistor of claim 1, wherein a thickness of the capping layer is in a range of 10 nm to 300 nm.

10. The thin film transistor of claim 1, wherein the capping layer comprises a material different from a material contained in the gate electrode.

11. The thin film transistor of claim 1, further comprising:
a source electrode and a drain electrode spaced apart from each other and contacting the active layer respectively,
wherein at least one of the source electrode or the drain electrode contacts the capping layer.

12. The thin film transistor of claim 1, the gate insulating layer comprises a first gate insulating layer and a second gate insulating layer,
wherein the capping layer is on the first gate insulating layer and gate electrode is on the second gate insulating layer.

13. A manufacturing method of a thin film transistor comprising:
forming an active layer on a substrate;
forming a gate insulating layer on the active layer;
forming a capping layer on the gate insulating layer;
heat treating the gate insulating layer; and
forming a gate electrode on the gate insulating layer.

14. The manufacturing method of claim 13, wherein a temperature that the gate insulating layer is heat treated is in a range of 60° C. to 450° C.

15. A display apparatus comprising the thin film transistor of claim 1.
